(19) United States
(12) Patent Application Publication
(10) Pub. No.: US 2009/0021271 A1
(43) Pub. Date: Jan. 22, 2009

(54) Measuring the On-Resistance of a Transistor Load Path

(75) Inventors: Giuseppe Bernacchia, Padova (IT); Giovanni Capodivacca, Padova (IT)

Correspondence Address: BANNER & WITCOFF, LTD.;Attorneys for client 007052, 1100 13th STREET, N.W., SUITE 1200, WASHINGTON, DC, 20005-4051, US

(73) Assignee: INFINEON TECHNOLOGIES AUSTRIA AG, Villach (AT)

(21) Appl. No.: 11/780,821

(22) Filed: Jul. 20, 2007

(51) Int. Cl. G01R 27/08

(52) U.S. Cl. 324/693

(57) ABSTRACT

Methods, and apparatuses for performing them, including applying a control signal to a control terminal of a transistor, to switch the transistor to an on-state such that the transistor carries a load current through a load-path of the transistor; measuring a voltage drop across the load-path of the transistor while the load current is passing through the load-path of the transistor, yielding a first measurement value; feeding a test current into the load-path of the transistor, such that the test current and the load current are combined; measuring a voltage drop across the load-path of the transistor while the combined test and load currents are passing through the load-path of the transistor, a second measurement value; and determining an on-resistance of the load-path of the transistor from a difference of the first and second measurement values.

### BACKGROUND

Switching regulators such as direct-current to direct-current (DC to DC) switching regulators often employ a control loop with current feedback. An easy, inexpensive and therefore attractive method for sensing load currents of a transistor is to measure the voltage drop over a load-path (e.g., source-to-drain path) of the respective transistor. Such a method does not require any external components and is lossless because it makes use of a parameter inherent to the transistor, i.e. the on-resistance. On the other hand, other methods such as measuring the voltage drop over a shunt-resistor entails a loss of power proportional to the resistance of the shunt-resistor.

In order to be able to determine the load current of a transistor by measuring the voltage drop over the load-path of the transistor, it has been necessary for the on-resistance of the load-path of the transistor to be known. At the present time, the resistance value given by suppliers of the transistors is used for calculating the load current from the measured voltage drop over the load-path of the transistor. The resistance values of the on-resistance given by suppliers or manufacturers often exhibit tolerance ranges of 40 percent of its nominal value, what entails intolerable inaccuracies of the current measurement. Additionally, the resistance value of the on-resistance of a transistor can vary considerably over temperature. Consequently, there is a general need to provide a way for in-circuit measurement of the on-resistance of a load-path of a transistor in order to be able to precisely measure the on-resistance of a transistor during operation for performing a calibration or recalibration of a current measurement of the load current through the transistor.

### SUMMARY

Various aspects are described herein. For example, some aspects are directed to a method including the following: applying a control signal to a control terminal of a transistor, to switch the transistor to an on-state such that the transistor carries a load current through a load-path of the transistor; measuring a voltage drop across the load-path of the transistor while the load current is passing through the load-path of the transistor, yielding a first measurement value; feeding a test current into the load-path of the transistor, such that the test current and the load current are combined; measuring a voltage drop across the load-path of the transistor while the combined test and load currents are passing through the load-path of the transistor, a second measurement value; and determining an on-resistance of the load-path of the transistor from a difference of the first and second measurement values.

Further aspects are directed to providing apparatuses for performing the above method and/or other methods.

These and other aspects of the disclosure will be apparent upon consideration of the following detailed description of illustrative aspects.

### BRIEF DESCRIPTION OF THE DRAWINGS

A more complete understanding of the present disclosure may be acquired by referring to the following description in consideration of the accompanying drawings, in which like reference numbers indicate like features, and wherein:

FIG. 1 is a schematic diagram of an illustrative embodiment of a circuit for determining the load current of a transistor by measuring the voltage drop across the load-path of the transistor having a known on-resistance.

FIG. 2a is a schematic diagram of an illustrative embodiment of a circuit arrangement for an in-circuit measurement of the on-resistance of a transistor in order to be able to perform a current measurement by measuring the voltage drop across a load-path of the transistor having an a-priori unknown on-resistance.

FIG. 2b is a schematic diagram of the circuit of FIG. 2a being illustratively adapted for precalibrating the shunt-resistor that is employed for measuring the test current.

### DETAILED DESCRIPTION

The various aspects summarized previously may be embodied in various forms. The following description shows by way of illustration various examples in which the aspects may be practiced. It is understood that other examples may be utilized, and that structural and functional modifications may be made, without departing from the scope of the present disclosure.

Except where explicitly stated otherwise, all references herein to two or more elements being “coupled,” “connected,” and “interconnected” to each other is intended to broadly include both (a) the elements being directly connected to each other, or otherwise in direct communication with each other, without any intervening elements, as well as (b) the elements being indirectly connected to each other, or otherwise in indirect communication with each other, with one or more intervening elements.

Illustrative embodiments of apparatuses and methods will be described herein for measuring the on-resistance of a load-path of a transistor, which may allow in-circuit measurements such as power metal-oxide-semiconductor field-effect transistors (MOSFETs) or other high or low power switching devices.

For example, a method may be provided for measuring an on-resistance of a load-path of a transistor which has a control terminal and is connected between the first and the second supply terminal. The method may include the following: applying a control signal to the control terminal of the transistor for switching the transistor into an on-state, such that the transistor carries a load current, measuring a voltage drop across the load-path of the transistor yielding a first measurement value, feeding a test current into the load-path of the transistor, such that the test current and the load current superpose, measuring a voltage drop across the load-path of the transistor yielding a second measurement value, and determining the on-resistance of the load-path of the transistor from difference of the first and second measurement value.

The step of measuring the voltage drop across the load-path of the transistor may further include amplifying by a first factor the voltage drop across the load-path of the transistor yielding the first measurement value, and digitizing the first measurement value yielding a first digital value.

In another example, the test current may be provided by a current source. The test current may also be determined by a resistance being connected between the load-path of the transistor and one of the supply terminals, wherein the resistance may be a series circuit of a shunt-resistor and a further resistor for limiting the current. The value of the test current may be determined by measuring the voltage drop across the shunt-resistor.

According to further illustrative embodiments, a circuit arrangement may be provided for measuring an on-resistance of a load-path of a first transistor is provided. The first transistor may be connected between a first and a second supply terminal and carries a load current. The circuit arrangement may include a measurement device connected with the first transistor for measuring the voltage drop across the load-path of the first transistor and for providing a measurement signal being a representation of the voltage drop, a switchable current source for providing a test current to the load-path of the first transistor, such that the test current and the load current can superpose, the current source being capable of being switched on and off by a switch which is responsive to a control signal, an evaluation circuit adapted for providing a control signal for the switch, for storing the measurement signal, and for calculating the on-resistance of the load-path of the first transistor from the test current, an actual measurement signal, and a stored measurement signal, where at least one of the measurement signals has been measured with the current source switched on.

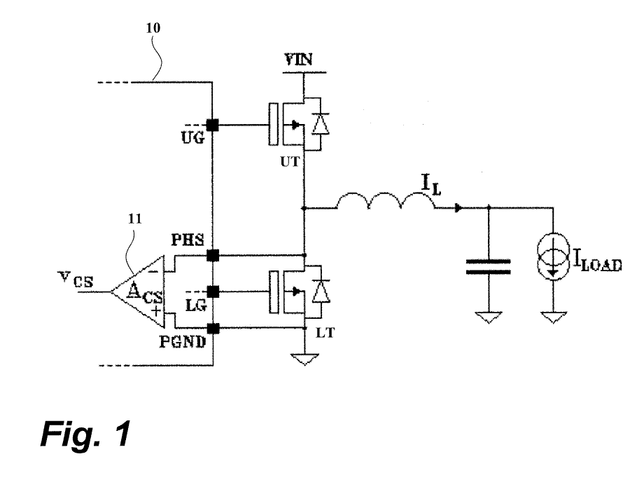

Turning to the figures, FIG. 1 depicts a circuit diagram of an illustrative embodiment of a half bridge including a high-side transistor UT having its source and drain connected between first supply terminal VIN and an output terminal, and a low-side transistor LT having its source and drain connected between the output terminal and a second supply terminal GND. A load circuit represented by an inductor, a capacitor and a current source is connected to the output terminal of the half bridge, the output terminal providing a load current I_{L} to the load circuit. Each transistor of the half bridge includes a control terminal (e.g., the gate of the respective transistor) connected to a control circuit 10 that may be integrated in a semiconductor chip. The control circuit 10 includes first and second terminals (which may be semiconductor chip pins accessible from outside the chip) UG and LG being connected with the control terminals of the high-side transistor UT and the low-side transistor LT. The first and the second terminals UG and LG are connected to driver circuits for high-side and the low-side transistor of the half bridge (not shown), the driver circuits being also part of the control circuit 10 in the semiconductor chip.

The control circuit 10 further includes a first amplifier 11 connected to the load terminals of the low-side transistor LT of the half bridge for amplifying the voltage drop across the load-path of the low-side transistor LT. This voltage drop across the low path is amplified by a factor A_{CS}. The output signal of the first amplifier 11 is a first measurement signal v_{CS}. Assuming the high-side transistor UT is in an off-state and the low-side transistor LT is in an on-state, the output current I_{L} has to flow through the load-path of the low-side transistor LT resulting in an voltage drop of R_{ON}·I_{L} across the load-path, wherein R_{ON} denotes the on-resistance of the low-side transistor LT. Accordingly, the output of the first amplifier 11, that is the first measurement signal v_{CS}, equals:

ν_{cs}=A_{cs}·R_{ON}·I_{L} (1)

The first measurement signal v_{CS} is, according to equation (1), proportional to the current I_{L} through the load-path of the low-side transistor LT. For actually calculating the current I_{L} through the load-path of the transistor the on-resistance R_{ON} of the transistor has to be known. FIG. 1 shows a load current measurement of the low-side transistor of a half bridge. Of course, the load current of the high-side transistor UT of the half bridge may be measured in an analogue manner.

As mentioned above, the resistance values for the on-resistance R_{ON} may vary due to tolerances in the production process, so that, as a consequence, the resistance values given by the manufactures or the suppliers of power transistors may exhibit a tolerance range of up to 40 percent of the nominal value, what entails a very inaccurate current measurement results. Moreover the on-resistance R_{ON} of a transistor may change over temperature, and this temperature behavior may be non-linear. However, it may be desired to provide a method for calibrating the current measurement circuit in order to potentially achieve a more accurate measurement of the load current I_{L}.

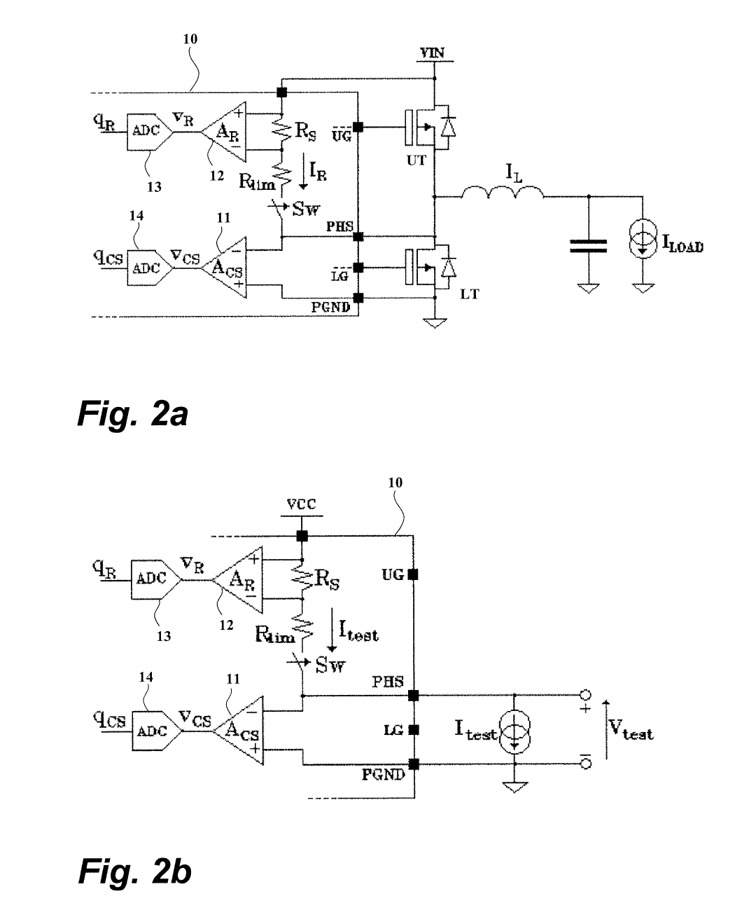

FIG. 2a shows a circuit diagram of an illustrative embodiment of a control circuit 10 including a circuit arrangement for measuring the load current through a load-path of a transistor similar to the circuit arrangement of FIG. 1. The control circuit 10 of FIG. 2a additionally includes circuit components for measuring the a-priori unknown on-resistance R_{ON} of the load-path of the transistor whose load current is to be measured. The measured on-resistance R_{ON} may be used to determine the actual value of the load current through the transistor, i.e. the on-resistance R_{ON} may be measured for calibrating the load current measurement.

In the example of FIG. 2a, the transistor whose load current is to be measured is a low-side transistor LT of a half bridge. Similar to FIG. 1, the control circuit 10 of FIG. 2a may be used for driving and controlling the half bridge connected to the control circuit 10. The control circuit 10 includes a current measurement circuit with an amplifier 11 and an analog-to-digital converter 14. The inputs of the amplifier 11 are connected via terminals PHS and PGND (which may be semiconductor chip pins accessible from the outside of the chip) to the first and the second load terminal of the low-side transistor LT respectively, such that the voltage drop across the load-path of the transistor LT is amplified by the amplifier 11 by a gain factor A_{CS} yielding a first measurement signal v_{CS} which is the output signal of the amplifier 11. The first measurement signal v_{CS} is supplied to the analog-to-digital converter 14 converted into a first sequence of a digital values q_{CS}(k). The first load terminal of the transistor LT is connected to the first supply terminal VIN via a series circuit of a switch Sw, a shunt-resistor R_{S}, and a further resistor Rₗᵢₘ. The further resistor Rₗᵢₘ is not necessarily a separate resistive component but may also be formed by the on-resistance of the switch Sw. If the supply voltage varies over a wide range it may be useful to use an (e.g. electronically) adjustable resistor as further resistor Rₗᵢₘ, so that the resistance of the resistor can be increased when the supply voltage increases.

In the shown example, if the low-side transistor LT is in an on-state and switch Sw is closed, a test current I_{R} is injected into the load-path of the transistor LT. The test current I_{R} flowing from the first supply terminal VIN through the load-path of the transistor LT to the second supply terminal GND may be determined by observing the voltage drop over the shunt-resistor R_{S}. Therefore a second amplifier 12 may have its inputs connected to a first and a second terminal of the shunt-resistor R_{S} respectively and provide as its output signal a second measurement signal v_{R} that is proportional to the test current I_{R} and calculated as follows:

ν_{R}=A_{R}·R_{S}·I_{R}, (2)

wherein the amplifier 12 has a second gain factor A_{R}. The second measurement signal v_{R} is supplied to a second analog-to-digital converter 13 for converting the second measurement signal V_{R} into a second sequence of digital values q_{R}(k).

An illustrative embodiment of a method for measuring the on-resistance of the load-path of the transistor LT performed by means of the control circuit 10 of FIG. 2a may involve the following, for example:
(A) Applying a control signal to the control terminal LG of the transistor LT for switching the transistor LT into an on-state, such that the transistor LT carries a load current I_{L}. In this state of operation the high-side switch UT of the half bridge may be normally (but not necessarily) in an off-state.
(B) Measuring the voltage drop across the load-path of the transistor LT yielding a first measurement value v_{CS}(k) of the first measurement signal v_{CS}.
(C) Feeding a test current I_{R} into the load-path of the transistor LT, such that the test current I_{R} and the load current I_{L} superpose. Since the transistor LT provides a low-resistance current path for the test current I_{R}, the test current I_{R} does not flow into the load circuit, but it sunken by the low-side transistor LT.
(D) Measuring a voltage across the load-path of the transistor LT yielding a second measurement value v_{CS}(k+1) of the first measurement signal v_{CS}.
(E) Determining the on-resistance R_{ON} of the load-path of the transistor LT from the difference of the first and the second measurement value v_{CS}(k)−v_{CS}(k+1).

It can be easily derived that the first measurement value v_{CS}(k) and the second measurement value v_{CS}(k+1) can be calculated as follows:

ν_{CS}(k)=A_{CS}·R_{ON}·I_{L}, (3)

ν_{CS}(k+1)=A_{CS}·R_{ON}·(I_{L}−I_{R}). (4)

Taking the difference of the first measurement value V_{CS}(k) and the second measurement value V_{CS}(k+1), that is the difference between equations (3) and (4), yields

ν_{CS}(k)−ν_{CS}(k+1)=ACS·R_{ON}·I_{R}. (5)

If the test current I_{R} is known, the on-resistance R_{ON} may be calculated according to equation (5). The test current I_{R} may be supplied by any current source. In the example of FIG. 2a, the test current I_{R} is supplied by the first supply terminal VIN via a series circuit of a shunt-resistor R_{S} and a current-limiting further resistor Rₗᵢₘ. As mentioned above, the test current I_{R} may be measured by observing the voltage drop over the shunt-resistor R_{S}, and the test current may be calculated from the measured voltage according to equation (2). Substituting equation (2) into equation (5) yields the following expression for the on-resistance R_{ON}:

$${R}_{ON} = \frac{{v}_{CS} ( k ) - {v}_{CS} ( k + 1 )}{{v}_{R} ( k + 1 ) \frac{{A}_{CS}}{{A}_{R} {R}_{S}}} = \frac{{v}_{CS} ( k ) - {v}_{CS} ( k + 1 )}{g \cdot {v}_{R} ( k + 1 )} , \qquad ( 6 )$$

wherein the variable g denotes a scaling factor which is equal to A_{CS}/(A_{R}R_{S}) and a value v_{R}(k+1) of the second measurement signal v_{R} (further denoted as “third measurement value) represents the test current I_{R}.

The calculation of the on-resistance R_{ON} may be performed manually and/or automatically, such as digitally by any computer and/or processor, e.g., an arithmetic/logic-unit (ALU), microcontroller, etc. For a digital signal processing the first measurement value v_{CS} (k), the second measurement value v_{CS} (k+1), and the third measurement value v_{R} (k+1) may be replaced by their digital representations (first digital value q_{CS}(k), second digital value q_{CS} (k+1), and third digital value q_{R} (k+1)). The on-resistance are may be then calculated (cf. equation 6) as the quotient of the difference q_{CS} (k)−q_{CS} (k+1) and a digital representation (q_{R}·A_{CS}/(A_{R}R_{S}) of the test current I_{R}.

The above described determination of the on-resistance R_{ON} for calibrating the current measurement of the load current of the transistor under test may involve the value of the shunt-resistor R_{S} to be known. Any error in the value of the shunt-resistor R_{S} may propagate and potentially result in a respective systematic error in the calculated value for the on-resistance R_{ON} and therefore in a systematic error in the load current measurement as well. It may be therefore useful to measure the value of the shunt-resistor R_{S} once, for example, during chip testing after the production process. The measured value for the shunt-resistor R_{S} may then be saved into memory, such as a non-volatile memory (e.g., an EEPROM) accessible to the computer or processor that may also be used to perform the above-mentioned calculations.

FIG. 2b shows an illustrative embodiment of a circuit that may be used for measuring the shunt-resistor R_{S} using a precalibrated current source being connected to the control circuit 10 in place of the load-path of the low-side transistor LT. When switch Sw is closed, a test current flows from a first supply terminal (VCC) via the shunt resistor R_{S} and the current limiting resistor Rₗᵢₘ into the current source which replaces the load-path of the low-side transistor LT of FIG. 2a. In this example, the test current is forced to assume a value Iₜₑₛₜ by the current source, since the current source is precalibrated to sink an exactly defined current Iₜₑₛₜ. The resistance value of the shunt-resistor R_{S} may be calculated from the voltage drop across the shunt-resistor R_{S}.

Measuring the shunt-resistance R_{S} may involve the following, for example:
(a) Forcing the test current I_{R} to assume a predefined current value Iₜₑₛₜ by means of a current source, the test current I_{R} thereby flowing through the shunt-resistor R_{S}. It may be desirable that the control circuit 10 is not connected to the transistor LT or, if connected to a transistor, that a control signal is applied to the control terminal of the respective transistor such that the transistor is switched into an off-state.
(b) Measuring a voltage drop R_{S} ·Iₜₑₛₜ across the shunt-resistor R_{S} yielding a fourth measurement value V_{R}(j). This fourth measurement value V_{R}(j) is the output voltage of the second amplifier 12 and may be calculated by:

ν_{R}(j)=A_{R}·R_{S}·Iₜₑₛₜ, (7)
wherein the symbol j represents a time-index at the time the measurement is performed. The fourth measurement value V_{R}(j) may be digitized by the analog-to-digital-converter 13, yielding a fourth digital value q_{R}(j).
(c) Determining a resistance value of the shunt-resistor from the fourth measurement value V_{R} (j) and the predefined current value Iₜₑₛₜ. This calculation may be also performed digitally.

The calculated resistance value for the shunt-resistor R_{S} then may be saved into the memory as explained above for the use in further calculations that are performed in order to obtain measurement values for the on-resistance R_{ON} as explained with reference to FIG. 2a.

1. A method, comprising:
applying a control signal to a control terminal of a transistor, to switch the transistor to an on-state such that the transistor carries a load current through a load-path of the transistor;
measuring a voltage drop across the load-path of the transistor while the load current is passing through the load-path of the transistor, yielding a first measurement value;
feeding a test current into the load-path of the transistor, such that the test current and the load current are combined;
measuring a voltage drop across the load-path of the transistor while the combined test and load currents are passing through the load-path of the transistor, a second measurement value; and
determining an on-resistance of the load-path of the transistor from a difference of the first and second measurement values.

2. The method of claim 1, further comprising:
amplifying by a first factor the voltage drop across the load-path of the transistor yielding the first measurement value,
digitizing the first measurement value, yielding a first digital value,
amplifying by the first factor the voltage drop across the load-path of the transistor yielding the second measurement value,
digitizing the second measurement value, yielding a second digital value.

3. The method of claim 1, further comprising determining the test current by measuring a voltage drop across a first resistor that is in series with a second resistor to yield a third measurement value, the first and second resistors being coupled to a node between the load-path of the transistor and a power supply node.

4. The method of claim 4, further comprising:
amplifying by a second factor the voltage drop across the first resistor yielding the third measurement value; and
digitizing the third measurement value, yielding a third digital value.

5. A method, comprising:
applying a control signal to a control terminal of a transistor to switch the transistor into an on-state such that the transistor carries a load current,
amplifying by a first factor a voltage drop across a load-path of the transistor while the load current is carried through the transistor, yielding a first measurement value,
digitizing the first measurement value, yielding a first digital value,
feeding a test current into the load-path of the transistor, such that the test current and the load current are combined;
amplifying by the first factor a voltage drop across the load-path of the transistor while the combined load and test currents are carried by the transistor, yielding a second measurement value;
digitizing the second measurement value, yielding a second digital value,
determining a difference between the first digital value and the second digital value; and
determining a quotient of the difference and a digital representation of the test current.

6. The method of claim 5, further comprising determining the test current by measuring a voltage drop across a first resistor that is in series with a second resistor to yield a third measurement value, the first and second resistors being coupled to a node between the load-path of the transistor and a power supply node.

7. The method of claim 6, further comprising:
amplifying by a second factor the voltage drop across the first resistor yielding the third measurement value; and
digitizing the third measurement value, yielding a third digital value.

8. The method of claim 6, further comprising:
forcing the test current to assume a predefined current value using a current source, the test current flowing through the first resistor;
measuring a voltage drop across the first resistor while the test current is being forced, yielding a fourth measurement value; and
determining a resistance value of the first resistor from the fourth measurement value and the predefined current value.

9. An apparatus, comprising:
a measurement device coupled to a transistor and configured to measure a voltage drop across a load-path of the transistor and to generate a measurement signal representing the voltage drop;
a switchable current source configured to provide a test current to the load-path of the transistor such that the test current and the load current are combined, the current source being switchable on and off in response to a control signal; and
an evaluation device configured to generate the control signal, to store a first instance of the measurement signal representing a measurement of the voltage drop taken by the measurement device while the current source is switched off, and to determine an on-resistance of the load-path of the transistor from the test current, a second instance of the measurement signal representing a measurement of the voltage drop taken by the measurement device while the current course is switched on, and the stored first instance of the measurement signal.

10. The apparatus of claim 9, further comprising an amplifier configured to amplify the voltage drop across the load-path of the first transistor.

11. The apparatus of claim 10, wherein the evaluation device comprises an analog-to-digital-converter having an input coupled to an output of the amplifier and being configured to generate a digital value representing the voltage drop across the load-path of the first transistor.

12. The apparatus of claim 11, where the evaluation device comprises an arithmetic unit configured to calculate a difference of the digital value representing the voltage drop over the load path with the current source switched on and of the digital value representing the voltage drop over the load path with the current source switched off, and further configured to calculate a quotient of the difference and a digital value proportional to the test current.

13. The apparatus of claim 9, wherein the switchable current source comprises a shunt resistor, and wherein a voltage across the shunt resistor depends upon the test current.

14. The apparatus of claim 13, wherein the evaluation device comprises an amplifier configured to amplify the voltage across the shunt resistor.

15. The apparatus of claim 14, wherein the evaluation device comprises an analog-to-digital-converter having an input coupled to an output of the amplifier and configured to generate a digital value representing the test current.

16. An apparatus, comprising:
a semiconductor integrated circuit chip, comprising:
a first chip pin;
a second chip pin;
a third chip pin;
a first amplifier having a first input and a second input, the first input of the first amplifier coupled to the first chip pin;
a first resistor coupled between the first and second inputs of the amplifier;
a second resistor switchably coupled between the first resistor and the second chip pin; and
a second amplifier having a first input coupled to the second chip pin and a second input coupled to the third chip pin.

17. The apparatus of claim 16, wherein the semiconductor chip further comprises:
a first analog-to-digital converter coupled to an output of the first amplifier; and
a second analog-to-digital converter coupled to an output of the second amplifier.

18. The apparatus of claim 16, further comprising a first transistor having a source coupled to the first chip pin and a drain coupled to the second chip pin.

19. The apparatus of claim 18, further comprising:
a fourth chip pin, wherein the semiconductor integrated circuit chip is configured to provide a driving voltage, a gate of the first transistor being coupled to the fourth chip pin.

20. The apparatus of claim 18, further comprising a second transistor having a source coupled to the second chip pin and a drain coupled to the third chip pin.

21. The apparatus of claim 20, further comprising a load coupled in parallel with the second transistor between the second chip pin and the third chip pin.
